(19) United States
(12) Patent Application Publication
(10) Pub. No.: US 2017/0373215 A1
(43) Pub. Date: Dec. 28, 2017

(54) HEAT-CURABLE SILICONE RESIN COMPOSITION FOR PRIMARILY ENCAPSULATING PHOTOCOUPLER, PHOTOCOUPLER ENCAPSULATED BY SAME, AND OPTICAL SEMICONDUCTOR DEVICE HAVING SUCH PHOTOCOUPLER

(71) Applicant: Shin-Etsu Chemical Co., Ltd., Tokyo (JP)

(72) Inventors: Yoshihiro TSUTSUMI, Annaka-shi (JP); Tadashi TOMITA, Annaka-shi (JP)

(73) Assignee: Shin-Etsu Chemical Co., Ltd., Tokyo (JP)

(21) Appl. No.: 15/591,477

(22) Filed: May 10, 2017

(30) Foreign Application Priority Data
Jun. 23, 2016 (JP) 2016-124061

(51) Int. Cl. H01L 31/16; C08L 83/04

(52) U.S. Cl. CPC H01L 31/16; C08L 83/04; C08L 2205/025

(57) ABSTRACT

Provided are a heat-curable silicone resin composition for primarily encapsulating photocoupler that is superior in heat resistance and curability, has no stain at the time of being molded and after being cured, and exhibits a small change in a light transmissibility; a photocoupler encapsulated by such composition; and an optical semiconductor device having such photocoupler. The heat-curable silicone resin composition contains
(A) a condensation reaction-type resinous organopolysiloxane solid at 25° C.;
(B) an organopolysiloxane having a linear diorganopolysiloxane residue, and at least one cyclohexyl group or phenyl group in one molecule;
(C) an inorganic filler;
(D) an organic metal-based condensation catalyst;
(E) a zirconium-carrying ion trapping agent; and
(F) a mold release agent.

### BACKGROUND OF THE INVENTION

### Field of the Invention

The present invention relates to a heat-curable silicone resin composition for primarily encapsulating photocoupler; a photocoupler encapsulated by such composition; and an optical semiconductor device having such photocoupler.

### Background Art

Optical devices have become more important in various fields in recent years as significant improvements have been made in communication speed and capacity. Particularly, a photocoupler is a device employing both a light-emitting element and a light-receiving element, and is capable of converting an incoming electric signal into a light through the light-emitting element and then sending such light to the light-receiving element as to thus transmit the signal. Therefore, a photocoupler often has a double-layered structure, since it is critical to highly efficiently transmit only the light from the light-emitting element to the light-receiving element, and the light from the light-emitting element has to be transmitted while blocking the lights from outside. Further, it is also required that properties such as a moisture resistance reliability and a flame retardancy be imparted. Thus, a light-emitting element is usually at first encapsulated by a primary encapsulation resin having a high light transmission capability i.e. a high transparency, and then encapsulated by a secondary encapsulation resin with a light blocking effect. Conventionally, silicone gels have been used as primary encapsulation resins, and epoxy resins have been used as secondary encapsulation resins. Meanwhile, in recent years, there have been more cases where only the periphery of a light-receiving element or a light-emitting element is at first encapsulated by a silicone gel, and an epoxy resin is then used as both the primary and secondary encapsulation resins, for the purpose of lowering cost and protecting the element(s) from the outside.

The efficiency of a photocoupler is expressed by CTR (Current Transfer Ratio) which can be obtained as a ratio between the current of a light-emitting element and the electromotive force of a light-receiving element. In order to achieve a high CTR value, required is a light transmissibility as high as that of a far-red light at a wavelength of about 700 to 1,000 nm.

In recent years, materials are required to have a higher reliability, since, for example, the temperature of a usage environment tends to be higher than before. JP-A-2009-203290 and JP-A-2010-006880 disclose epoxy resins for photocoupler that yield a high light transmissibility and a reflow resistance. However, even these epoxy resins have been required to meet higher requirements in terms of light resistance.

A silicone resin is an example of a material with a higher heat resistance. JP-A-2012-057000 discloses a heat-curable silicone resin composition. This composition is obtained by a condensation reaction known for its low reaction speed. As described in JP-A-2012-057000, a poor curability is exhibited when using an (organic) metal catalyst. Further, not only a poor storability will be exhibited, but stains will easily occur at the time of performing molding, if using an organic amine-based catalyst such as DBU. Although JP-A-2012-057000 also discloses the usage of a microcapsulated catalyst, a sufficient curability still cannot be achieved under such usage. In addition, there has been a problem that this composition cannot be used in an optical semiconductor-related device, because stains will occur as a result of performing secondary curing even under the presence of such microcapsulated catalyst.

### SUMMARY OF THE INVENTION

Therefore, it is an object of the present invention to provide a heat-curable silicone resin composition for primarily encapsulating photocoupler, which is superior in heat resistance and curability, has no stain at the time of being molded and after being cured, and exhibits a small change in a light transmissibility; a photocoupler encapsulated by such composition; and an optical semiconductor device having such photocoupler.

The inventors of the present invention diligently conducted a series of studies and completed the invention as follows. That is, the inventors found that the following heat-curable silicone resin composition could serve as a resin for primarily encapsulating photocoupler that is capable of achieving the aforementioned objects.

[1]

A heat-curable silicone resin composition for primarily encapsulating photocoupler, comprising:

(A) 70 to 95 parts by mass of a condensation reaction-type resinous organopolysiloxane solid at 25° C.;

(B) 5 to 30 parts by mass of an organopolysiloxane having a linear diorganopolysiloxane residue, containing silanol units at a ratio of 0.5 to 10% with respect to all siloxane units, and having at least one cyclohexyl group or phenyl group in one molecule, the linear diorganopolysiloxane residue being represented by the following general formula 2:

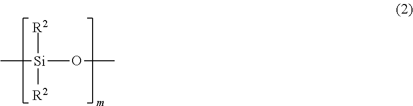

wherein R² independently represents a monovalent hydrocarbon group selected from a hydroxyl group, an alkyl group having 1 to 3 carbon atoms, a cyclohexyl group, a phenyl group, a vinyl group and an allyl group, m represents an integer of 5 to 50, and a total of the components (A) and (B) is 100 parts by mass;

(C) an inorganic filler in an amount of 300 to 900 parts by mass per the total of 100 parts by mass of the components (A) and (B);

(D) an organic metal-based condensation catalyst in an amount of 0.01 to 10 parts by mass per the total of 100 parts by mass of the components (A) and (B);

(E) a zirconium-carrying ion trapping agent in an amount of 2 to 30 parts by mass per the total of 100 parts by mass of the components (A) and (B); and

(F) a mold release agent in an amount of 0.5 to 10.0 parts by mass per the total of 100 parts by mass of the components (A) and (B).

[2]

The heat-curable silicone resin composition for primarily encapsulating photocoupler according to [1], further comprising a coupling agent as a component (G).

[3]

The heat-curable silicone resin composition for primarily encapsulating photocoupler according to [1] or [2], wherein the condensation reaction-type resinous organopolysiloxane (A) is a resinous organopolysiloxane having a weight-average molecular weight of 1,000 to 20,000 in terms of polystyrene, and being represented by the following average composition formula (1):

(CH₃)ₐSi(OR¹)_{b}(OH)_{c}O_{(4-a-b-c)/2} (1)

wherein R¹ represents an identical or different organic group having 1 to 4 carbon atoms; a, b and c are numbers satisfying 0.8≦a≦1.5, 0≦b≦0.3, 0.001≦c≦0.5 and 0.801≦a+b+c<2.
[4]

A photocoupler encapsulated by the heat-curable silicone resin composition for primarily encapsulating photocoupler as set forth in any one of [1] to [3].

[5]

An optical semiconductor device having the photocoupler as set forth in [4].

The heat-curable silicone resin composition of the invention is superior in heat resistance and curability, has no stain at the time of being molded and after being cured, and exhibits a small change in a light transmissibility. Thus, the composition of the invention is useful as a heat-curable silicone resin composition for primarily encapsulating photocoupler.

### DETAILED DESCRIPTION OF THE INVENTION

The present invention is described in greater detail hereunder.

### (A) Condensation Reaction-Type Resinous Organopolysiloxane Solid at 25° C.

An organopolysiloxane as a component (A) forms a cross-linked structure with a linear organopolysiloxane as a component (B) under the presence of a later-described organic metal-based condensation catalyst as a component (D).

The organopolysiloxane as the component (A) may be a resinous (i.e. branched or three-dimensional network structured) organopolysiloxane represented by the following average composition formula (1), and having a weight-average molecular weight of 1,000 to 20,000 in terms of polystyrene when measured by gel permeation chromatography (GPC) using tetrahydrofuran or the like as a developing solvent.

(CH₃)ₐSi(OR′)_{b}(OH)_{c}O_{(4-a-b-c)/2} (1)

In the above formula (1), R¹ represents an identical or different organic group having 1 to 4 carbon atoms; a, b and c are numbers satisfying 0.8≦a≦1.5, 0≦b≦0.3, 0.001≦c≦0.5 and 0.801≦a+b+c<2.

With regard to the above average composition formula (1), an organopolysiloxane-containing composition where “a” as a methyl group content is smaller than 0.8 is not preferable, because a cured product of such composition will become excessively hard in a way such that a poor crack resistance will be resulted. Further, it is also not preferable when a is greater than 1.5, because it will be difficult for a resinous organopolysiloxane obtained to solidify. It is preferred that the methyl group content in the component (A) be 0.8≦a≦1.2, more preferably 0.9≦a≦1.1.

In the above average composition formula (1), when “b” as an alkoxy group content is greater than 0.3, a resinous organopolysiloxane obtained tends to exhibit a small molecular weight in a way such that the crack resistance may often be impaired. It is preferred that the alkoxy group content in the component (A) be 0.001≦b≦0.2, more preferably 0.01≦b≦0.1.

In the above average composition formula (1), it is not preferable when “c” as a content of hydroxyl groups bonded to Si atoms is greater than 0.5, because while a cured product of a resinous organopolysiloxane obtained may exhibit a high hardness due to a condensation reaction at the time of performing heat curing, the cured product will exhibit a poor crack resistance. Further, it is also not preferable when c is smaller than 0.001, because a resinous organopolysiloxane obtained tends to exhibit a high melting point in a way such that problems associated with workability may occur. It is preferred that the content of the hydroxyl groups bonded to Si atoms in the component (A) be 0.01≦c≦0.3, more preferably 0.05≦c≦0.2. In order to control the value of c to 0.001≦c≦0.5, it is preferable to control a complete condensation rate of alkoxy groups in a raw material to 86 to 96%. It is not preferable when such complete condensation rate is lower than 86%, because the value of c will exceed 0.5 in a way such that a lower melting point will be resulted. Further, it is also not preferable when such complete condensation rate is greater than 96%, because the value of c will fall below 0.001 in a way such that the melting point tends to become excessively high.

Here, the complete condensation rate refers to a ratio of a molar number of all the alkoxy groups in one molecule that have been subjected to condensation reaction to a total molar number of the material.

In this way, in the above average composition formula (1), it is preferred that a+b+c fall into a range of 0.9≦a+b+c≦1.8, more preferably 1.0≦a+b+c≦1.5.

In the above average composition formula (1), R¹ represents an organic group having 1 to 4 carbon atoms, examples of which include alkyl groups such as a methyl group, an ethyl group and an isopropyl group. Here, a methyl group and an isopropyl group are preferred in terms of raw material availability.

It is preferred that the resinous organopolysiloxane as the component (A) have an weight-average molecular weight of 1,000 to 20,000, more preferably 1,500 to 10,000, or even more preferably 2,000 to 8,000, in terms of polystyrene when measured by GPC. When such molecular weight is smaller than 1,000, it will be difficult for a resinous organopolysiloxane obtained to solidify. Further, when this molecular weight is greater than 20,000, fluidity will decrease due to an excessively high viscosity of a composition obtained, which may then result in a poor formability.

The weight-average molecular weight referred to in the present invention is a weight-average molecular weight measured by gel permeation chromatography (GPC) under the following conditions, using polystyrene as a standard substance.

### Measurement Condition

Developing solvent: Tetrahydrofuran
Flow rate: 0.35 mL/min

### Detector: RI

Column: TSK-GEL H type (by Tosoh Corporation)
Column temperature: 40° C.
Sample injection volume: 5 μL

The component (A) represented by the above average composition formula (1) can be expressed as a combination of Q unit (SiO_{4/2}), T unit (CH₃SiO_{3/2}), D unit ((CH₃)₂ SiO_{2/2}) and M unit ((CH₃)₃ SiO_{1/2}). When the component (A) is expressed in such manner, it is preferred that a ratio of a number of T units contained to a total number of all siloxane units be not lower than 70% (70% to lower than 100%), more preferably not lower than 75% (75% to lower than 100%), particularly preferably not lower than 80% (80% to lower than 100%). When such ratio of the number of T units contained is lower than 70%, an overall balance between, for example, the hardness, adhesion and outer appearance of a cured product may be disrupted. Here, a remnant may be M, D and Q units, and a ratio of a sum of these units to all siloxane units is not higher than 30% (0 to 30%), particularly higher than 0% but not higher than 30%. Thus, it is preferred that T unit be present at a ratio of lower than 100%.

The component (A) represented by the above average composition formula (1) can be obtained as a hydrolyzed condensate of an organosilane represented by the following general formula (3).

(CH₃)ₙSiX₄₋ₙ (3)

In the above formula (3), X represents a halogen atom such as a chlorine atom or an alkoxy group having 1 to 4 carbon atoms; n represents 0, 1 or 2.

In such case, it is preferred that X be either a chlorine atom or a methoxy group in terms of obtaining an organopolysiloxane solid at 25° C.

Examples of the hydrolyzed condensate of the organosilane represented by the above formula (3) include an organotrichlorosilane such as methyltrichlorosilane; an organotrialkoxysilane such as methyltrimethoxysilane and methyltriethoxysilane; a diorganodialkoxysilane such as dimethyldimethoxysilane and dimethyldiethoxysilane; a tetrachlorosilane; and a tetraalkoxysilane such as tetramethoxysilane and tetraethoxysilane.

While the hydrolyzed condensate of the organosilane may be produced by a common method, it is preferred that the silane compound be hydrolyzed and condensed under the presence of a catalyst. As such catalyst, there may be used both an acid catalyst and an alkali catalyst. Preferable examples of an acid catalyst include an organic acid catalyst such as acetic acid; and an inorganic acid catalyst such as hydrochloric acid and sulfuric acid. Preferable examples of an alkali catalyst include an alkali metal hydroxide such as sodium hydroxide and potassium hydroxide; and an organic alkali catalyst such as tetramethylammonium hydroxide. One specific example is that when using a silane containing a chloro group(s) as a hydrolyzable group(s), a target hydrolyzed condensate with an appropriate molecular weight can be obtained by utilizing as catalysts a hydrogen chloride gas and hydrochloric acid that occur at the time of performing water addition.

An amount of water used to perform hydrolysis and condensation is normally 0.9 to 1.6 mol, preferably 1.0 to 1.3 mol, per 1 mol of a total amount of the hydrolyzable groups (e.g. chloro groups) in the hydrolyzed condensate of the organosilane. When such amount is within the range of 0.9 to 1.6 mol, a later-described composition tends to exhibit a superior workability, and a cured product thereof tends to exhibit a superior toughness.

It is preferred that the hydrolyzed condensate of the organosilane be used after being hydrolyzed in an organic solvent such as alcohols, ketones, esters, cellosolves or aromatic compounds. Specifically, preferred are, for example, alcohols such as methanol, ethanol, isopropyl alcohol, isobutyl alcohol, n-butanol and 2-butanol; or aromatic compounds such as toluene and xylene. Here, isopropyl alcohol, toluene or a combined system of isopropyl alcohol/toluene are more preferable in terms of achieving a superior curability of a composition obtained and a superior toughness of a cured product thereof.

It is preferred that a reaction temperature for hydrolysis and condensation be 10 to 120° C., more preferably 20 to 80° C. When the reaction temperature is within these ranges, gelation will not take place easily such that there can be obtained a solid hydrolyzed condensate that can be used in a subsequent step.

It is preferred that the organopolysiloxane as the component (A) be added to the heat-curable silicone resin composition of the invention by an amount of 8.0 to 30% by mass, more preferably 8.5 to 20% by mass, or even more preferably 9.0 to 18% by mass.

### (B) Organopolysiloxane

In order to alleviate a stress and improve the crack resistance, the heat-curable silicone resin composition of the invention uses an organopolysiloxane as a component (B). Specifically, the organopolysiloxane (B) has a linear diorganopolysiloxane residue represented by the following formula (2); contains silanol units at a ratio of 0.5 to 10% with respect to all siloxane units; and has at least one, preferably two or more cyclohexyl groups or phenyl groups in one molecule.

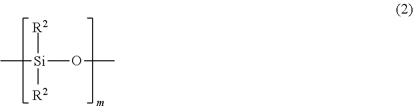

In the above formula (2), each R² independently represents a group selected from a hydroxyl group; an alkyl group having 1 to 3 carbon atoms; a cyclohexyl group; a phenyl group; a vinyl group; and an allyl group. R² preferably represents a methyl group or a phenyl group. m represents an integer of 5 to 50, preferably 8 to 40, more preferably 10 to 35. When m is smaller than 5, a cured product obtained tends to exhibit a poor crack resistance in a way such that a device containing such cured product may exhibit warpage. Further, when m is greater than 50, the cured product obtained tends to exhibit an insufficient mechanical strength.

In addition to D unit (R²₂ SiO_{2/2}) represented by the above formula (2), the component (B) may also contain at least one unit selected from: D unit (R₂ SiO_{2/2}) that is not represented by the formula (2); M unit (R₃SiO_{1/2}); and T unit (RSiO_{3/2}). In terms of cured product properties, it is preferred that a ratio of D unit:M unit:T unit be 90 to 24:75 to 9:50 to 1, particularly preferably 70 to 28:70 to 20:10 to 2 (provided that a total of these units is 100). Here, R represents a hydroxyl group, a methyl group, an ethyl group, a propyl group, a cyclohexyl group, a phenyl group, a vinyl group or an allyl group. In addition, the component (B) may further contain Q unit (SiO_{4/2}). The organopolysiloxane as the component (B) has at least one cyclohexyl group or phenyl group in one molecule.

It is preferred that not less than 30% (e.g. 30 to 90%), particularly preferably not less than 50% (e.g. 50 to 80%) of D units (R²₂ SiO_{2/2}) as represented by the general formula (2) be present in a continuous fashion in the organopolysiloxane as the component (B). Further, it is preferred that a weight-average molecular weight of the component (B) in terms of polystyrene be 3,000 to 120,000, more preferably 10,000 to 100,000, when measured by gel permeation chromatography (GPC). In terms of, for example, a workability and curability of a composition obtained, it is preferable when the molecular weight of the component (B) is within these ranges, because the component (B) will be in the form of either a solid or a semisolid under such condition.

The component (B) can be synthesized by combining compounds as raw materials of the above units in a manner such that a required molar ratio(s) will be achieved in a produced polymer, and then hydrolyzing and condensing the same under the presence of, for example, an acid.

Examples of raw materials for T unit (RSiO_{3/2}) include trichlorosilanes such as methyltrichlorosilane, ethyltrichlorosilane, propyltrichlorosilane, phenyltrichlorosilane and cyclohexyltrichlorosilane; and alkoxysilanes such as trimethoxysilanes individually corresponding to these trichlorosilanes.

Examples of raw materials for D unit (R²₂ SiO_{2/2}) as the linear diorganopolysiloxane residue represented by the above formula (2) are as follows.

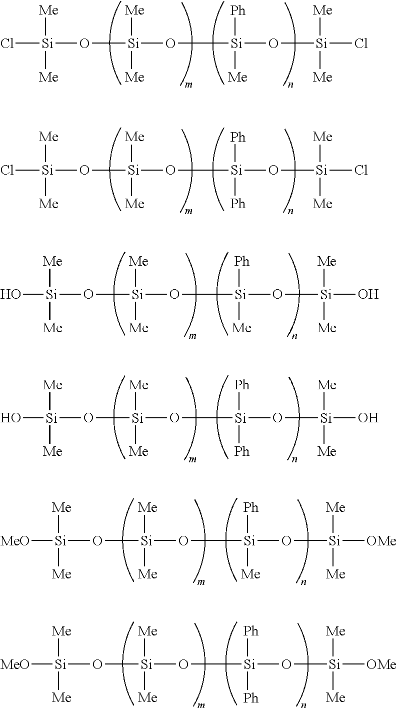

Here, m represents an integer of 3 to 48 (average value), n represents an integer of 0 to 48 (average value), and m+n represents 3 to 48 (average value, repeating units may be in either a block or random sequence).

Further, examples of raw materials for units such as M unit and D unit that is not represented by the formula (2), include mono- or dichlorosilanes such as Mee PhSiCl, Me₂ViSiCl, Ph₂MeSiCl, Ph₂ViSiCl, Me₂SiCl₂, MeEtSiCl₂, ViMeSiCl₂, Ph₂SiCl₂ and PhMeSiCl₂; and mono- or dialkoxysilanes such as mono- or dimethoxysilanes individually corresponding to these chlorosilanes. Here, Me represents a methyl group, Et represents an ethyl group, Ph represents a phenyl group, and Vi represents a vinyl group.

The component (B) can be obtained by combining these compounds as raw materials at a given molar ratio(s), and then reacting the same in, for example, the following manner. That is, phenylmethyldichlorosilane, phenyltrichlorosilane, a dimethyl silicone oil having chlorine atoms at both ends and 21 Si atoms, and toluene are added and mixed together, followed by delivering a mixed silane into the liquid by drops, and then cohydrolyzing the same at 30 to 50° C. for an hour. Next, a product thus obtained is left to age at 50° C. for an hour, followed by pouring water thereinto to wash the same. Later, azeotropic dehydration is performed, and/or polymerization is performed at 25 to 40° C. using ammonia or the like as a catalyst, followed by performing filtration and stripping under a reduced pressure.

The organopolysiloxane as the component (B) contains silanol units (siloxane units having silanol groups) at a ratio of 0.5 to 10%, preferably about 1 to 5%, with respect to all siloxane units. Examples of such silanol units include R(HO)SiO_{2/2} unit, R(HO)₂SiO_{1/2} unit and R₂(HO)SiO_{1/2} unit (R represents any of the abovementioned groups, except for hydroxyl group). Since this organopolysiloxane contains silanol groups, a condensation reaction can take place between such organopolysiloxane and the hydroxyl group-containing resinous polyorganosiloxane (A) represented by the above formula (1).

The component (B) is added in an amount by which a mass ratio between the component (A) and the component (B) becomes 95:5 to 70:30, preferably 90:10 to 80:20. When the component (B) is added in an excessively small amount, there can only be achieved a small effect of improving a continuous formability of a composition obtained, and it will be difficult for a cured product obtained to acquire a low warpage property and the crack resistance. Further, when the component (B) is added in a large amount, the viscosity of a composition obtained will easily increase in a way such that formability may be impaired.

### (C) Inorganic Filler

An inorganic filler as component (C) is added to improve a strength of a cured product of the silicone resin composition of the invention, and improve fluidity. As the inorganic filler (C), there may be used those commonly added to a silicone resin composition and an epoxy resin composition. Examples of the inorganic filler as the component (C) include silicas such as a spherical silica, a molten silica and a crystalline silica; silicon nitride; aluminum nitride; boron nitride; glass fibers; glass particles; and antimony trioxide. Particularly, since a superior light extraction efficiency will be achieved when the refractive index of a silicone resin and the refractive index of an inorganic filler are close to each other, it is preferable to use an inorganic filler having a refractive index of 1.35 to 1.60, more preferably 1.40 to 1.55. A molten silica and glass particles are preferred in terms of fluidity; and a crushed silica and glass fibers are preferred in terms of reinforcement. A molten spherical silica is especially preferred in terms of formability, fluidity, burr control and transmissivity.

In the present invention, a refractive index refers to a value measured by an Abbe refractometer at a temperature of 25° C. and at a wavelength of 589.3 nm, in accordance with JIS K 0062:1992.

It is preferred that an average particle diameter of the inorganic filler be 5 to 40 μm, particularly preferably 7 to 35 μm. An average particle diameter smaller than 5 μm will not only cause viscosity to significantly increase and fluidity to decrease, but will also lead to a decrease in transmissivity. When this average particle diameter is larger than 40 μm, burrs will occur at an extremely massive level. Those with an average particle diameter of 5 to 40 μm are commercially available, and can also be produced by a known method. Further, in order to make the silicone resin composition highly fluid, it is preferred that there be used in combination those having a fine particle size of 0.1 to 3 μm, those having a middle particle size of 4 to 8 μm and those having a large particle size of 10 to 50 μm. Here, the average particle diameter refers to a cumulative mass average value D₅₀ (or median diameter) obtained through particle size distribution measurement using a laser diffraction method.

The inorganic filler as the component (C) is added in an amount of 300 to 900 parts by mass, preferably 400 to 800 parts by mass, per a total of 100 parts by mass of the components (A) and (B). When the inorganic filler (C) is added in an amount of smaller than 300 parts by mass, there may not be achieved a sufficient strength. Further, when the inorganic filler (C) is added in an amount of greater than 900 parts by mass, filling failures due to an increase in viscosity and loss of flexibility will occur in a way such that failures such as peeling inside an element may occur. The inorganic filler as the component (C) is contained in the whole composition by an amount of 10 to 92% by mass, particularly preferably 50 to 88% by mass.

### (D) Organic Metal-Based Condensation Catalyst

The organic metal-based condensation catalyst as the component (D) is a condensation catalyst used to cure the heat-curable organopolysiloxanes as the components (A) and (B). Particularly, the organic metal-based condensation catalyst is selected in view of, for example, a stability, a film hardness, a non-yellowing property and a curability of the components (A) and (B). Preferable examples of the organic metal-based condensation catalyst (D) include an organic acid zinc, an organic aluminum compound and an organic titanium compound. Specific examples thereof include organic metal-based condensation catalysts such as zinc benzoate, zinc octylate, p-tert-butyl zinc benzoate, zinc laurate, zinc stearate, aluminum triisopropoxide, aluminum acetylacetonate, ethylacetoacetate aluminum di (normal butylate), aluminum-n-butoxy diethyl acetoacetate ester, tetrabutyl titanate, tetraisopropyl titanate, tin octylate, cobalt naphthenate and tin naphthenate. Among these specific examples, zinc benzoate is preferably used.

A cured product will easily discolor if using an organic compound-based condensation catalyst such as a basic organic compound or an acid organic compound. Further, since these organic compound-based condensation catalysts have a poor preservation stability, it is not preferable to use them in a material associated with outer appearance and color tone, such as an optical semiconductor.

The organic metal-based condensation catalyst is added in an amount of 0.01 to 10 parts by mass, preferably 0.1 to 2.5 parts by mass, per the total of 100 parts by mass of the components (A) and (B). When the amount of the organic metal-based condensation catalyst added is within these ranges, a silicone resin composition obtained will exhibit a favorable and stable curability.

### (E) Zirconium-Carrying Ion Trapping Agent

An ion trapping agent as a component (E) is originally used to more effectively improve a high-temperature storability of a semiconductor device that has been manufactured using an encapsulation resin composition and is thus equipped with an encapsulation resin. Although the ion trapping agent (E) may be a negative ion trapping agent, a positive ion trapping agent or a positive/negative ion trapping agent, a positive ion trapping agent and a positive/negative ion trapping agent are preferred.

It is required that the ion trapping agent as the component (E) of the invention be that carrying zirconium. While a zirconium-carrying ion trapping agent alone is not effective, it is capable of improving a hot hardness as a cocatalyst when coexisting with the organic metal-based condensation catalyst as the component (D). Further, the ion trapping agent (E) is also capable of restricting a heat deterioration of a mold release agent as a component (F), and improving a heat resistance thereof.

With regard to the zirconium-carrying ion trapping agent as the component (E), although there are no particular restrictions on the rest part thereof, it is preferred that a carrier be at least one of hydrotalcites and an inorganic ion exchanger such as a multivalent metal acid salt. Among these carriers, hydrotalcites are particularly preferred from the perspective of improving the high-temperature storability.

It is preferred that an amount of zirconium carried be 0.1 to 10 meq/g, particularly preferably 1 to 8 meq/g, as a total exchange amount of each ion. When the amount of zirconium carried is within these ranges, the high-temperature storability of a semiconductor device can be more effectively improved. Here, the total ion exchange amount refers to an ion exchange amount in a 0.1 N sodium hydroxide aqueous solution or a 0.1 N hydrochloric acid.

Further, as the zirconium-carrying ion trapping agent (E), there may be used a commercially available product such as IXE-100, IXE-800, IXEPLAS-A1, IXEPLAS-A2 and IXEPLAS-B1 (all by TOAGOSEI CO., LTD.).

The zirconium-carrying ion trapping agent is added in an amount of 2 to 30 parts by mass, preferably 2.5 to 15 parts by mass, per the total of 100 parts by mass of the components (A) and (B). When the amount of the zirconium-carrying ion trapping agent added is within these ranges, a silicone resin composition obtained will exhibit a favorable curability and heat resistance. When the zirconium-carrying ion trapping agent is added in an amount of greater than 30 parts by mass, fluidity will excessively decrease in a way such that filling failures may occur.

### (F) Mold Release Agent

The mold release agent as the component (F) is added to improve a mold releasability at the time of performing molding, and is added in an amount of 0.2 to 10.0 parts by mass, preferably 0.5 to 5.0 parts by mass, per the total of 100 parts by mass of the components (A) and (B). Examples of such mold release agent include synthetic waxes such as a natural wax, an acid wax, a polyethylene wax and a fatty acid wax which are typical examples of a synthetic wax. Here, preferred are calcium stearate having a melting point of 120 to 140° C.; stearic acid ester; and a hardened castor oil.

In addition to the abovementioned components, optional components described below may also be added to the present invention.

### (G) Coupling Agent

A coupling agent as a component (G) is added to the heat-curable silicone resin composition of the invention to improve a bonding strength between the resin and inorganic filler, and further improve an adhesion strength to a plated metal substrate. The coupling agent as the component (G) may, for example, be a silane coupling agent or a titanate coupling agent.

Specifically, preferable examples of the coupling agent as the component (G) include γ-glycidoxypropyltrimethoxysilane; γ-glycidoxypropylmethyldiethoxysilane; an epoxy functional alkoxysilane such as β-(3,4-epoxycyclohexyl) ethyltrimethoxysilane; and a mercapto functional alkoxysilane such as γ-mercaptopropyltrimethoxysilane. These coupling agents are preferable because the resin, for example, will not discolor even when left in a high-temperature environment. There are no particular restrictions on an amount of the coupling agent used and a method for using the same.

It is preferred that the component (G) be added in an amount of 0.1 to 8.0 parts by mass, particularly preferably 0.5 to 6.0 parts by mass, per the total of 100 parts by mass of the components (A) and (B). When the component (G) is added in an amount of smaller than 0.1 parts by mass, there may not be achieved a sufficient adhesion effect on a base material and a secondary sealing resin. Further, when the component (G) is added in an amount of greater than 8.0 parts by mass, viscosity will decrease in an extremely significant manner, which may then cause voids.

### Other Additives

Various additives may be further added to the heat-curable silicone resin composition of the invention, if necessary. For example, in order to improve the properties of a resin, there may be added to the composition of the invention additives such as an other organopolysiloxane(s), a silicone powder, a silicone oil, a thermoplastic resin, a thermoplastic elastomer, an organic synthetic rubber or a light stabilizer, without impairing the effects of the present invention.

### Production Method of Heat-Curable Silicone Resin Composition

A production method of the heat-curable silicone resin composition of the invention is as follows. That is, the silicone resin, inorganic filler, organic metal-based condensation catalyst, zirconium-carrying ion trapping agent, mold release agent, coupling agent and other additives are at first combined together at given ratios, followed by thoroughly and homogenously mixing the same using a mixer or the like, and then melting and mixing a mixture thus obtained using a heated roll mill, a kneader, an extruder or the like. Next, a product thus prepared is cooled and solidified, and then crushed into an appropriate size so as to obtain a molding material of the heat-curable silicone resin composition. A cured product of the silicone resin composition of the invention exhibits a linear expansion coefficient of not larger than 30 ppm/K, preferably not larger than 25 ppm/K, at a temperature higher than a glass-transition temperature.

### Molding Method Using Encapsulation Material

A transfer molding method and a compression molding method are examples of the most common molding method using a primary encapsulation material of the invention to encapsulate a photocoupler. The transfer molding method is performed using a transfer molding machine under a molding pressure of 5 to 20 N/mm². Particularly, the transfer molding method is performed at a molding temperature of 120 to 190° C. for a molding time of 60 to 500 sec, particularly preferably at a molding temperature of 150 to 185° C. for a molding time of 30 to 180 sec. Further, the compression molding method is performed using a compression molding machine at a molding temperature of 120 to 190° C. for a molding time of 30 to 600 sec, particularly preferably at a molding temperature of 130 to 160° C. for a molding time of 120 to 300 sec. In each molding method, post curing may be further performed at 150 to 185° C. for 0.5 to 20 hours.

### Working Example

The invention is described in detail hereunder with reference to working and comparative examples. However, the present invention is not limited to the following working examples.

Raw materials used in working and comparative examples are as follows.

A weight-average molecular weight referred to in the present invention hereunder is that measured by GPC under the following measurement conditions.

### Molecular Weight Measurement Condition

Developing solvent: Tetrahydrofuran
Flow rate: 0.35 mL/min

### Detector: RI

Column: TSK-GEL H type (by Tosoh Corporation)
Column temperature: 40° C.
Sample injection volume: 5 μL

### (A) Synthesis of Resinous Organopolysiloxane

### Synthesis Example 1

Methyltrichlorosilane of 100 parts by mass and toluene of 200 parts by mass were put into a 1 L flask, followed by delivering thereinto by drops a mixed solution of water of 8 parts by mass and isopropyl alcohol of 60 parts by mass under ice cooling. Specifically, 5 hours were spent in delivering the mixed solution dropwise within an inner temperature range of −5 to 0° C., followed by performing heating so as to stir a solution thus obtained at a reflux temperature for 20 min. A mixed solution thus prepared was then cooled to room temperature, followed by spending 30 min in delivering dropwise thereinto water of 12 parts by mass under a temperature of not higher than 30° C., and then stirring a product thus obtained for 20 min. Water of 25 parts by mass was then delivered by drops thereinto, followed by stirring a reaction mixture thus obtained at 40 to 45° C. for 60 min. Later, water of 200 parts by mass was added to such reaction mixture so as to separate an organic layer therefrom. This organic layer was then washed until it had become neutral, followed by performing azeotropic dehydration, filtration and stripping under a reduced pressure so as to obtain, as a colorless and transparent solid, 36.0 parts by mass of a resinous organopolysiloxane (A-1) represented by the following average formula (A-1) (melting point 76° C., weight-average molecular weight 3,060, refractive index 1.43).

(CH₃)_{1.0}Si(OC₃H₇)_{0.07}(OH)_{0.10}O_{1.4} (A-1)

### (B) Synthesis of Organopolysiloxane

### Synthesis Example 2

Mixed together were 100 g (4.4 mol %) of phenylmethyldichlorosilane; 2,100 g (83.2 mol %) of phenyltrichlorosilane; 2,400 g (12.4 mol %) of a dimethyl polysiloxane oil having 21 Si atoms and both ends thereof blocked by chlorine atoms; and 3,000 g of toluene, followed by delivering dropwise thereinto the aforementioned silane that had already been mixed into water of 11,000 g, and then cohydrolyzing the same at 30 to 50° C. for an hour. Later, a cohydrolyzed product thus obtained was left to age at 30° C. for an hour, followed by pouring water to wash the same, and then performing azeotropic dehydration, filtration and stripping under a reduced pressure so as to obtain a colorless and transparent product (organosiloxane (B-1)). This siloxane (B-1) exhibited a melt viscosity of 5 Pa·s when measured by an ICI cone-plate viscometer at 150° C., a weight-average molecular weight of 50,000 and a refractive index of 1.49. Further, an amount of silanol units in such siloxane was 3.3%.

[(Me₂SiO)₂₁]_{0.124}(PhMeSiO)_{0.044}(PhSiO_{1.5})_{0.832} (B-1)

### (C) Inorganic Filler

(C-1): Molten spherical silica (MAR-T815/53C by TATSUMORI LTD.; average particle diameter 10 μm)

### (D) Organic Metal-Based Condensation Catalyst

(D-1): Zinc benzoate (by Wako Pure Chemical Industries, Ltd.)

### (E-1) Zirconium-Carrying Ion Trapping Agent

(E-1-1) Zirconium/magnesium-based ion trapping agent (IXEPLAS-A1 by TOAGOSEI CO., LTD.)

(E-1-2) Zirconium/magnesium-based ion trapping agent (IXEPLAS-A2 by TOAGOSEI CO., LTD.)

(E-1-3) Zirconium-based ion trapping agent (IXE-100 by TOAGOSEI CO., LTD.)

### (E-2) Ion Trapping Agent for Comparative Example

(E-2-1) Bismuth-based ion trapping agent (IXE-500 by TOAGOSEI CO., LTD.)

(E-2-2) Magnesium/aluminum-based ion trapping agent (DHT-4A-2 by Kyowa Chemical Industry Co., Ltd.)

### (F) Mold Release Agent

(F-1): Hardened castor oil (KAOWAX 85P by Kao Corporation.)

### (G) Coupling Agent

(G-1): 3-mercaptopropyltrimethoxysilane (KBM-803 by Shin-Etsu Chemical Co., Ltd.)

### Working Examples 1 to 7; Comparative Examples 1 to 4

In accordance with the composition ratios (parts by mass) shown in Table 1 and Table 2, a heat-curable silicone resin composition was produced by first using a heated twin roll mill, and then performing cooling and crushing. The following properties of the heat-curable silicone resin compositions produced at the various composition ratios were then measured, and the results thereof are shown in Table 1 and Table 2.

### Spiral Flow Value

A spiral flow value of each composition was measured using a mold manufactured in accordance with EMMI standard, and under conditions of molding temperature 175° C./molding pressure 6.9 N/mm²/molding time 120 sec.

### Hot Hardness

Molding was performed using a mold manufactured in accordance with JIS K 6911:2006, and under the conditions of molding temperature 175° C./molding pressure 6.9 N/mm²/molding time 120 sec, followed by immediately disassembling the mold, and using a Shore D hardness tester to measure a hot hardness of the molded product.

### Bending Strength and Bending Elastic Modulus at Room Temperature

Molding was performed using a mold manufactured in accordance with JIS K 6911:2006, and under the conditions of molding temperature 175° C./molding pressure 6.9 N/mm²/molding time 120 sec, followed by performing post curing at 180° C. for 4 hours. A bending strength and bending elastic modulus of the post-cured specimen were then measured at room temperature (25° C.).

### Light Transmissibility, Heat Resistance Test

A 50×50 mm cured product having a thickness of 0.35 mm was prepared under the conditions of molding temperature 175° C./molding pressure 6.9 N/mm²/molding time 120 sec, followed by using X-rite 8200 (by S.D.G K.K.) to measure a light transmissibility of such cured product at a wavelength of 740 nm. Next, the cured product was subjected to secondary curing at 180° C. for 4 hours, followed by likewise using X-rite 8200 to measure the light transmissibility of a cured product thus obtained at the wavelength of 740 nm. Later, a heat treatment was further performed at 180° C. for 500 hours, followed by likewise using X-rite 8200 (by S.D.G K.K.) to measure the light transmissibility of a heat-treated product thus obtained at the wavelength of 740 nm.

TABLE 1

| | | | | Working example | | | | | | |
|---|---|---|---|---|---|---|---|---|---|---|
| Composition (part by mass) | | | | 1 | 2 | 3 | 4 | 5 | 6 | 7 |
| (A) | Resinous organopolysiloxane | | A-1 | 90.0 | 90.0 | 90.0 | 90.0 | 90.0 | 90.0 | 90.0 |
| (B) | Organopolysiloxane | | B-1 | 10.0 | 10.0 | 10.0 | 10.0 | 10.0 | 10.0 | 10.0 |
| (C) | Inorganic filler | MAR-T815/53C | C-1 | 600.0 | 600.0 | 600.0 | 600.0 | 600.0 | 600.0 | 600.0 |
| (D) | Organic metal- | Zinc benzoate | D-1 | 1.0 | 1.0 | 1.0 | 1.0 | 1.0 | 1.0 | 1.0 |
| | based | | | | | | | | | |
| | condensation | | | | | | | | | |
| | catalyst | | | | | | | | | |
| (E) | Ion trapping | IXEPLAS-A1 | E-1-1 | 3.0 | 6.0 | | | | | |
| | agent | IXEPLAS-A2 | E-1-2 | | | 3.0 | 6.0 | | | 3.0 |
| | | IXE-100 | E-1-3 | | | | | 3.0 | 6.0 | 3.0 |
| (F) | Mold release | KAOWAX 85P | F-1 | 2.0 | 2.0 | 2.0 | 2.0 | 2.0 | 2.0 | 2.0 |
| | agent | | | | | | | | | |
| (G) | Coupling agent | KBM-803 | G-1 | 0.5 | 0.5 | 0.5 | 0.5 | 0.5 | 0.5 | 0.5 |
| Property | Spiral flow value | | inch | 27 | 24 | 25 | 24 | 23 | 23 | 24 |
| evaluation | Hot hardness | | | 48 | 59 | 50 | 60 | 52 | 63 | 60 |
| | Bending strength at room temperature | | MPa | 55 | 53 | 55 | 56 | 53 | 55 | 55 |
| | Bending elastic modulus at room | | MPa | 9900 | 10100 | 10000 | 10000 | 10100 | 10600 | 10200 |
| | temperature | | | | | | | | | |
| | Light | Shortly after molding | % | 70 | 71 | 71 | 71 | 68 | 70 | 71 |
| | transmissibility | After secondary | % | 70 | 69 | 70 | 71 | 68 | 70 | 70 |
| | (740 nm) | curing | | | | | | | | |
| | | After heat treatment | % | 67 | 67 | 68 | 70 | 65 | 68 | 68 |

TABLE 2

| | | | | Comparative example | | | |
|---|---|---|---|---|---|---|---|
| Composition (part by mass) | | | | 1 | 2 | 3 | 4 |
| (A) | Resinous organopolysiloxane | | A-1 | 90.0 | 90.0 | 90.0 | 90.0 |
| (B) | Organopolysiloxane | | B-1 | 10.0 | 10.0 | 10.0 | 10.0 |
| (C) | Inorganic filler | MAR-T815/53C | C-1 | 600.0 | 600.0 | 600.0 | 600.0 |
| (D) | Organic metal- | Zinc benzoate | D-1 | 1.0 | 1.0 | 1.0 | |
| | based | | | | | | |
| | condensation | | | | | | |
| | catalyst | | | | | | |
| (E) | Ion trapping | IXEPLAS-A2 | E-1-2 | | | | 30.0 |
| | agent | IXE-500 | E-2-1 | | 6.0 | | |
| | | DHT-4A-2 | E-2-2 | | | 6.0 | |
| (F) | Mold release | KAOWAX 85P | F-1 | 2.0 | 2.0 | 2.0 | 2.0 |
| | agent | | | | | | |
| (G) | Coupling agent | KBM-803 | G-1 | 0.5 | 0.5 | 0.5 | 0.5 |
| Property | Spiral flow value | | inch | 25 | 24 | 23 | Failed to |
| evaluation | Hot hardness | | | 19 | 16 | 20 | cure, unable |
| | Bending strength at room temperature | | MPa | 55 | 54 | 55 | to obtain |
| | Bending elastic modulus at room | | MPa | 10000 | 10200 | 10100 | target cured |
| | temperature | | | | | | product |
| | Light | Shortly after molding | % | 71 | 68 | 68 | |
| | transmissibility | After secondary | % | 64 | 62 | 62 | |
| | (740 nm) | curing | | | | | |
| | | After heat treatment | % | 60 | 61 | 60 | |

As shown in Table 1, it was confirmed that the heat-curable silicone resin composition of the invention had a high hot hardness, and was capable of being molded in a short period of time. In addition, it was also confirmed that the cured product of the composition of the invention had a high light transmissibility at an initial stage, and that there was almost no difference between the light transmissibility at the initial stage and a light transmissibility observed after performing the heat treatment in the heat resistance test. That is, it was confirmed that the cured product of the composition of the invention had a superior resistance to discoloration such as stains occurring due to thermal degradation after long-term use.

What is claimed is:

1. A heat-curable silicone resin composition for primarily encapsulating photocoupler, comprising:
(A) 70 to 95 parts by mass of a condensation reaction-type resinous organopolysiloxane solid at 25° C.;
(B) 5 to 30 parts by mass of an organopolysiloxane having a linear diorganopolysiloxane residue, containing silanol units at a ratio of 0.5 to 10% with respect to all siloxane units, and having at least one cyclohexyl group or phenyl group in one molecule, the linear diorganopolysiloxane residue being represented by the following general formula 2: 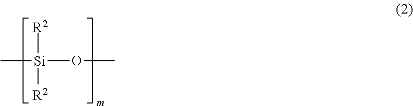
wherein R² independently represents a monovalent hydrocarbon group selected from a hydroxyl group, an alkyl group having 1 to 3 carbon atoms, a cyclohexyl group, a phenyl group, a vinyl group and an allyl group, m represents an integer of 5 to 50, and a total of the components (A) and (B) is 100 parts by mass;
(C) an inorganic filler in an amount of 300 to 900 parts by mass per the total of 100 parts by mass of the components (A) and (B);
(D) an organic metal-based condensation catalyst in an amount of 0.01 to 10 parts by mass per the total of 100 parts by mass of the components (A) and (B);
(E) a zirconium-carrying ion trapping agent in an amount of 2 to 30 parts by mass per the total of 100 parts by mass of the components (A) and (B); and
(F) a mold release agent in an amount of 0.5 to 10.0 parts by mass per the total of 100 parts by mass of the components (A) and (B).

2. The heat-curable silicone resin composition for primarily encapsulating photocoupler according to claim 1, further comprising a coupling agent as a component (G).

3. The heat-curable silicone resin composition for primarily encapsulating photocoupler according to claim 1, wherein the condensation reaction-type resinous organopolysiloxane (A) is a resinous organopolysiloxane having a weight-average molecular weight of 1,000 to 20,000 in terms of polystyrene, and being represented by the following average composition formula (1):
(CH₃)ₐSi(OR¹)_{b}(OH)_{c}O_{(4-a-b-c)/2} (1)
wherein R¹ represents an identical or different organic group having 1 to 4 carbon atoms; a, b and c are numbers satisfying 0.8≦a≦1.5, 0≦b≦0.3, 0.001≦c≦0.5 and 0.801≦a+b+c<2.

4. The heat-curable silicone resin composition for primarily encapsulating photocoupler according to claim 2, wherein the condensation reaction-type resinous organopolysiloxane (A) is a resinous organopolysiloxane having a weight-average molecular weight of 1,000 to 20,000 in terms of polystyrene, and being represented by the following average composition formula (1):
(CH₃)ₐSi(OR¹)_{b}(OH)_{c}O_{(4-a-b-c)/2} (1)
wherein R¹ represents an identical or different organic group having 1 to 4 carbon atoms; a, b and c are numbers satisfying 0.8≦a≦1.5, 0≦b≦0.3, 0.001≦c≦0.5 and 0.801≦a+b+c<2.

5. A photocoupler encapsulated by the heat-curable silicone resin composition for primarily encapsulating photocoupler as set forth in claim 1.

6. A photocoupler encapsulated by the heat-curable silicone resin composition for primarily encapsulating photocoupler as set forth in claim 2.

7. A photocoupler encapsulated by the heat-curable silicone resin composition for primarily encapsulating photocoupler as set forth in claim 3.

8. A photocoupler encapsulated by the heat-curable silicone resin composition for primarily encapsulating photocoupler as set forth in claim 4.

9. An optical semiconductor device having the photocoupler as set forth in claim 5.

10. An optical semiconductor device having the photocoupler as set forth in claim 6.

11. An optical semiconductor device having the photocoupler as set forth in claim 7.

12. An optical semiconductor device having the photocoupler as set forth in claim 8.
